(19) United States
(12) Patent Application Publication
(10) Pub. No.: US 2010/0148167 A1
(43) Pub. Date: Jun. 17, 2010

(54) MAGNETIC TUNNEL JUNCTION STACK

(75) Inventors: Renu Whig, Chandler, AZ (US); Frederick B. Mancoff, Chandler, AZ (US); Nicholas D. Rizzo, Gilbert, AZ (US); Phillip G. Mather, Maricopa, AZ (US)

Correspondence Address: INGRASSIA FISHER & LORENZ, P.C., 7010 E. COCHISE ROAD, SCOTTSDALE, AZ, 85253, US

(73) Assignee: EVERSPIN TECHNOLOGIES, INC., Chandler, AZ (US)

(21) Appl. No.: 12/333,763

(22) Filed: Dec. 12, 2008

(51) Int. Cl. H01L 43/02; H01L 43/12

(52) U.S. Cl. 257/43; 438/3; 257/421; 257/E43.006; 257/E43.001

(57) ABSTRACT

A magnetic tunnel junction (300) structure includes a layer (308) of iron having a thickness in the range of 1.0 to 5.0 Å disposed between a tunnel barrier (306) and a free magnetic element (310) resulting in high magnetoresistance (MR), low damping and an improved ratio V_{c}/V_{bd} of critical switching voltage to tunnel barrier breakdown voltage for improved spin torque yield and reliability while requiring only a low temperature anneal. This improved structure (300) also has a very low resistance-area product MgON diffusion barrier (312) between the free magnetic element (310) and an electrode (314) to prevent diffusion of the electrode into the free layer, which assists in keeping the damping, and therefore also the switching voltage, low. With the low annealing temperature, the breakdown voltage is high, resulting in a favorable ratio of V_{c}/V_{bd} and in a high proportion of devices switching before breakdown, therefore improving the yield and reliability of the devices.

### FIELD

The present invention generally relates to magnetic random access memory devices and more particularly to the magnetic tunnel junction stack of spin-transfer based MRAM devices.

### BACKGROUND

Magnetic random access memory (MRAM) is a nonvolatile memory technology that uses magnetization to represent stored data, in contrast to older RAM technologies that use electronic charges to store data. One primary benefit of MRAM is that it retains the stored data in the absence of electricity, i.e., it is a nonvolatile memory. Generally, MRAM includes a large number of magnetic cells formed on a semiconductor substrate, where each cell represents one data bit. A bit is written to a cell by changing the magnetization direction of a magnetic element within the cell, and a bit is read by measuring the resistance of the cell (low resistance typically represents a “0” bit and high resistance typically represents a “1” bit).

Magnetoresistive random access memories (MRAMs) combine magnetic components to achieve non-volatility, high-speed operation, and excellent read/write endurance. In a standard MRAM device 100, such as that illustrated in FIG. 1 for a single bit, information is stored in the magnetization directions (illustrated by arrows) of individual magnetic tunnel junctions (MTJs) 102. MTJ 102 generally includes an insulating tunnel barrier 106 between two ferromagnetic layers: free ferromagnetic layer (or simply “free magnet”) 104, and fixed ferromagnetic layer (or “fixed magnet”) 108. In a standard MRAM, the bit state is programmed to a “1” or “0” using applied magnetic fields 114 and 116 generated by currents flowing along adjacent conductors, e.g., orthogonally-situated digit line 118 and bit line 110. The applied magnetic fields 114 and 116 selectively switch the magnetic moment direction of free magnet 104 as needed to program the bit state. When layers 104 and 108 are aligned in the same direction, and a voltage is applied across MTJ 102, e.g., via isolation transistor 120 having a suitably controlled gate 121, a lower resistance is measured than when layers 104 and 108 are set in opposite directions.

The traditional MRAM switching technique depicted in FIG. 1 has some practical limitations, particularly when the design calls for scaling the bit cell to smaller dimensions. For example, since this technique requires two sets of magnetic field write lines, the array of MRAM cells is susceptible to bit disturbs, i.e., neighboring cells may be unintentionally altered in response to the write current directed to a given cell. Furthermore, decreasing the physical size of the MRAM cells results in lower magnetic stability against magnetization switching due to thermal fluctuations. The stability of the bit can be enhanced by utilizing a magnetic material for the free layer with a large magnetic anisotropy and therefore a large switching field, but then the currents required to generate a magnetic field strong enough to switch the bit are impractical in real applications.

In spin-transfer MRAM (ST-MRAM) devices, such as that shown in FIG. 2, the bits are written by forcing a current directly through the stack of materials that make up the MTJ 102, e.g., via current 202 controlled via isolation transistor 120. Generally speaking, the write current I_{DC}, which is spin polarized by passing through one ferromagnetic layer (104 or 108), exerts a spin torque on the subsequent layer. This torque can be used to switch the magnetization of free magnet 104 between two stable states by changing the write current polarity.

ST-MRAM virtually eliminates the problem of bit disturbs, results in improved data retention, and enables higher density and lower power operation for future MRAM. Since the current passes directly through the MTJ stack, the main requirements of the magnetic tunneling barrier for ST-MRAM include: low resistance-area product (RA), high magnetoresistance (MR), and high breakdown voltage. Moderate to low magnetization and low magnetic damping of the free layer is required for the devices to have low switching current density. MTJ material with MgO tunnel barriers and CoFeB (CFB) free layers are used in ST-MRAM as these result in very high MR at low RA. However, to obtain very high MR with MgO, the devices typically have to be annealed at temperatures as high as 350° C. or above. However, as the annealing temperature of the tunneling barrier increases, the breakdown voltage decreases. At temperatures above 325° C., the breakdown voltage of the tunneling barrier degrades significantly. This results in an unfavorable ratio of the required critical voltage (V_{c}) for switching to the breakdown voltage of the tunnel barrier layer (V_{bd}), which results in a high proportion of devices not able to switch before breaking down. Also, the damping of the free layer, which determines the rate of energy loss from a precessing magnetic moment to the lattice, increases as the anneal temperature of the material increases. This may be a result of metal diffusion at high temperatures, typically from the top electrode covering the free layer. The increased damping results in high switching currents. Therefore, although very high MR can be obtained by annealing the MTJ stack at higher temperatures, the overall performance of the device decreases.

Accordingly, it is desirable to provide a structure and method for obtaining high MR while maintaining low damping and a favorable low V_{c}/V_{bd} ratio. Furthermore, other desirable features and characteristics of the present invention will become apparent from the subsequent detailed description and the appended claims, taken in conjunction with the accompanying drawings and this background.

### BRIEF DESCRIPTION OF THE DRAWINGS

Embodiments of the present invention will hereinafter be described in conjunction with the following drawing figures, wherein like numerals denote like elements, and

FIG. 1 is a conceptual cross-sectional view of a previously known standard magnetic tunnel junction;

FIG. 2 is a cross-sectional view of a previously known spin-transfer magnetic tunnel junction;

FIG. 3 is a cross sectional view of a magnetic tunnel junction cell configured in accordance with an exemplary embodiment;

FIG. 4 is a graph comparing MR as a function of different anneal temperatures for the exemplary embodiment;

FIG. 5 is a graph comparing the damping constant for free layers annealed at various temperatures;

FIG. 6 is a graph comparing the ratio of critical voltage to breakdown voltage (V_{c}/V_{bd}) of the tunnel barrier layer for the exemplary embodiment;

FIG. 7 is a graph comparing breakdown and switching voltage distributions for devices material made with a conventional stack; and

FIG. 8 is a graph comparing breakdown and switching voltage distributions for devices made in accordance with the exemplary embodiment.

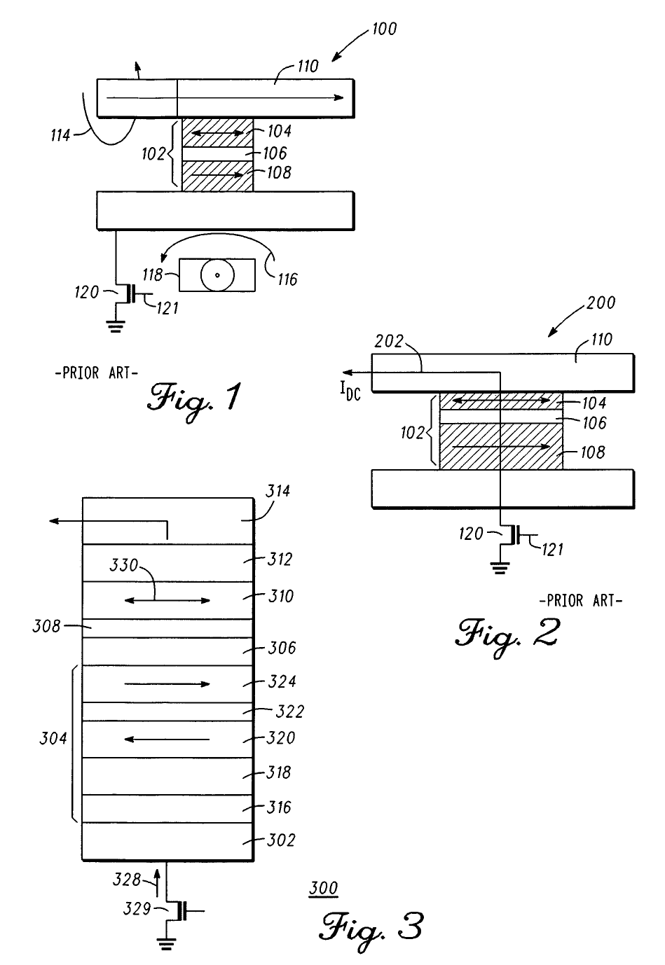

### DETAILED DESCRIPTION

The following detailed description is merely exemplary in nature and is not intended to limit the invention or the application and uses of the invention. Furthermore, there is no intention to be bound by any theory presented in the preceding background or the following detailed description.

A magnetic tunnel junction (MTJ) structure includes an MgO tunnel barrier and a CoFeB free layer that require a low temperature anneal, for example, less than 300° C., but results in high magnetoresistance (MR), low damping and an improved ratio V_{c}/V_{bd} of critical switching voltage to tunnel barrier breakdown voltage for improved spin torque yield and reliability. By adding very thin layers of pure Fe at the interface between the MgO tunneling barrier and the CoFeB free layer and using annealing temperatures of less than 300° C., higher MR values than the conventional stack and process (no Fe and 350° C. anneal) are obtained. This improved structure also has a very low resistance-area product (RA) MgON diffusion barrier between the CoFeB free layer and a top Ta electrode or cap to prevent the diffusion of Ta into CoFeB, which assists in keeping the damping, and therefore also the switching voltage low. With the annealing temperature below 300° C., the breakdown voltage is high, thus resulting in a favorable ratio of V_{c}/V_{bd} and in a high proportion of devices switching before breakdown, therefore improving the yield and reliability of the devices.

Though the exemplary embodiment of the MTJ is described with reference to spin-transfer MRAM (ST-MRAM), it may also be used in toggle-MRAM and magnetic sensors.

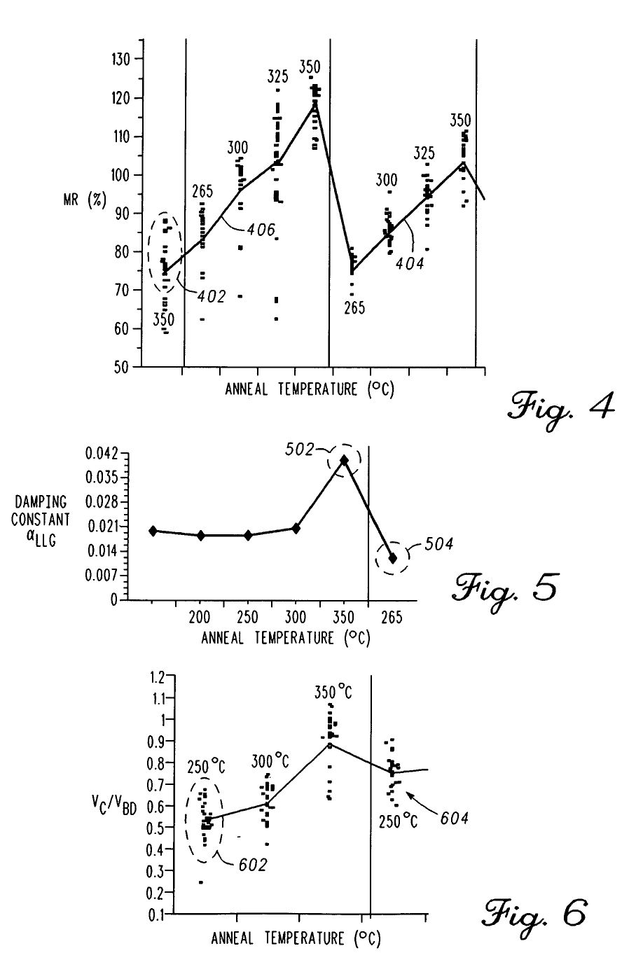

FIG. 3 is a side sectional view of an MRAM cell 300 configured in accordance with an exemplary embodiment of the invention. In practice, an MRAM architecture or device will include many MRAM cells 300, typically connected together in a matrix of columns and rows. MRAM cell 300 generally includes the following elements: a first electrode 302, a fixed magnetic element 304, an insulator (or tunnel barrier layer) 306, a free magnetic element 310 which contains a thin layer 308 of iron (Fe), a diffusion barrier 312, and a second electrode 314. In this exemplary embodiment, fixed magnetic element 304 includes a template/seed layer 316, a pinning layer 318, a pinned layer 320, a spacer layer 322, and a fixed layer 324. It should be understood that the structure of MRAM cell 300 may be fabricated in the reverse order, e.g., with the first electrode 302 formed either first or last.

First and second conductor 302, 314 are formed from any suitable material capable of conducting electricity. For example, conductors 302, 314 may be formed from at least one of the elements Al, Cu, Au, Ag, Ta or their combinations.

In the illustrated embodiment, fixed magnet element 304 is located between insulator 306 and electrode 302. Fixed magnet element 304 has a fixed magnetization that is either parallel or anti-parallel to the magnetization of free magnetic element 310. In the practical embodiment, fixed magnet element 304 includes a template or seed layer 316 formed on the electrode 302 for facilitating the formation of a pinning layer 318, for example IrMn, PtMn, FeMn, thereon. The template/seed layer 316 is preferably a non magnetic material, for example Ta, Al, Ru, but can also be a magnetic material, for example NiFe, CoFe. The pinning layer 318 determines the orientation of a magnetic moment of the pinned layer 320 formed thereon. The fixed layer 324 is formed on the spacer layer 322. The pinned magnetic layer 320 and fixed magnetic layer 324 have anti-parallel magnetizations, and may be formed from any suitable magnetic material, such as at least one of the elements Ni, Fe, Co, B, or their alloys as well as so-called half-metallic ferromagnets such as NiMnSb, PtMnSb, Fe₃O₄, or CrO₂. Spacer layer 322 is formed from any suitable nonmagnetic material, including at least one of the elements Ru, Os, Re, Cr, Rh, Cu, or their combinations. Synthetic antiferromagnet structures are known to those skilled in the art and, therefore, their operation will not be described in detail herein.

An insulator layer 306 is formed on the fixed magnetic element 304, and more specifically, on the fixed magnetic element 324. The insulator layer 306 comprises insulator materials such as AlOx, MgOx, RuOx, HfOx, ZrOx, TiOx, or the nitrides and oxidinitrides of these elements like MgON thereon.

In this exemplary embodiment, insulator 306 is located between free magnetic element 310 and fixed magnet element 304. More specifically, insulator 306 is located between free magnetic element 310 and fixed magnetic layer 324. Insulator 306 is formed from any suitable material that can function as an electrical insulator. For example, insulator 306 may be formed preferably from MgO, or from a material such as oxides or nitrides of at least one of Al, Si, Hf, Sr, Zr, Ru or Ti. For purposes of MRAM cell 300, insulator 306 serves as a magnetic tunnel barrier element and the combination of free magnetic element 310, insulator 306, and fixed magnet element 304 form a magnetic tunnel junction.

In the illustrated embodiment, free magnetic element 310 is located between the insulator material 306 and the electrode 314. Free magnetic element 310 is formed from a magnetic material having a variable magnetization. For example, free magnetic element 310 may be formed from at least one of the elements Ni, Fe, Co, B or their alloys as well as so-called half-metallic ferromagnets such as NiMnSb, PtMnSb, Fe₃O₄, or CrO₂. As with conventional MRAM devices, the direction of the variable magnetization of free magnetic element 310 determines whether MRAM cell 300 represents a “1” bit or a “0” bit. In practice, the direction of the magnetization of free magnetic element 310 is either parallel or anti-parallel to the direction of the magnetization of fixed magnet element 324.

Free magnetic element 310 has a magnetic easy axis that defines a natural or “default” orientation of its magnetization. When MRAM cell 300 is in a steady state condition with no current 328 applied (when transistor 329 is not activated), the magnetization of free magnetic element 310 will naturally point along its easy axis. As described in more detail below, MRAM cell 300 is suitably configured to establish a particular easy axis direction for free magnetic element 310. From the perspective of FIG. 3, the easy axis of free magnetic element 310 points either to the right or to the left (for example, in the direction of the arrow 330). In practice, MRAM cell 300 utilizes anisotropy, such as shape or crystalline anisotropy, in the free magnetic element 308 to achieve the orientation of the respective easy axes.

Electrode 314 serves as the data read conductor for MRAM cell 300. In this regard, data in MRAM cell 300 can be read in accordance with conventional techniques: a small current flows through MRAM cell 300 and electrode 314, and that current is measured to determine whether the resistance of MRAM cell 300 is relatively high or relatively low. The read current is much smaller than the current required to switch the free layer by spin-transfer in order to avoid disturbs caused by reading the cell.

In practice, MRAM cell 300 may employ alternative and/or additional elements, and one or more of the elements depicted in FIG. 3 may be realized as a composite structure or combination of sub-elements. The specific arrangement of layers shown in FIG. 3 merely represents one suitable embodiment of the invention.

The spin-transfer effect is known to those skilled in the art. Briefly, a current becomes spin-polarized after the electrons pass through the first magnetic layer in a magnet/non-magnet/magnet trilayer structure, where the first magnetic layer is substantially thicker or has a substantially higher magnetization than the second magnetic layer. The spin-polarized electrons cross the nonmagnetic spacer and then, through conservation of angular momentum, place a torque on the second magnetic layer, which switches the magnetic orientation of the second layer to be parallel to the magnetic orientation of the first layer. If a current of the opposite polarity is applied, the electrons instead pass first through the second magnetic layer. After crossing the nonmagnetic spacer, a torque is applied to the first magnetic layer. However, due to its larger thickness or magnetization, the first magnetic layer does not switch. Simultaneously, a fraction of the electrons will then reflect off the first magnetic layer and travel back across the nonmagnetic spacer before interacting with the second magnetic layer. In this case, the spin-transfer torque acts so as to switch the magnetic orientation of the second layer to be anti-parallel to the magnetic orientation of the first layer.

In accordance with the exemplary embodiment, a thin layer 308 of iron (Fe) is formed between the insulator 306 and the free magnetic element 310. The thickness of the layer 308 may be in the range of 1-5 Å, but preferably is in the range of 2.5 Å-5 Å (see U.S. Pat. No. 7,098,495 assigned to the assignee of the present application regarding high polarization insertion layers). By adding very thin layers of pure Fe at the interface between insulator 306 and the free magnetic element 310 and using annealing temperatures less than 350° C., and preferably less than 300° C., and more preferably at about 265° C., one can obtain MR values higher than the conventional stack and process (no Fe and 350° C. anneal). With the annealing temperatures below 300° C., the breakdown voltages are high, thus resulting in a favorable ratio of V_{c}/V_{bd} and in a high proportion of devices switching before breakdown, hence improving the yield and reliability of the devices. Further in accordance with the exemplary embodiment, a diffusion barrier 312 is formed between the free layer 310 and the electrode 314 (see U.S. Pat. No. 6,544,801 assigned to the assignee of the present application regarding diffusion barriers). This diffusion barrier 312 preferably is formed of low RA magnesium oxinitride (MgON) and has a thickness in the range of 8-20 Å, but preferably is in the range of 12 Å-16 Å. The diffusion barrier 312 prevents diffusion of tantalum into the free layer 310, thereby keeping the damping low and reducing critical currents.

FIG. 4 shows a comparison of MR for both a conventional material 402 and an improved MTJ stack 404, 406 as a function of anneal temperatures of the MTJ. With thin layers of Fe at the interface of MgO and the CoFeB free layer, MRs higher than with conventional stacks 402 (without Fe interfacial layers) can be achieved even at the lowest anneal temperatures. The line 404 represents 2.5 Å of Fe at the interface of MgO and CoFeB, while the line 406 represents 5 Å of Fe. These MRs are typically for MTJs with an RA of 4-7Ωμ² for 100 nanometer×200 nanometer area devices.

FIG. 5 shows damping as a function of anneal temperature for CoFeB free layers without a diffusion barrier and with a Ta cap (see U.S. Pat. Nos. 6,831,312 and 7,067,331 assigned to the assignee of the present application regarding CoFeB alloys). A conventional stack is represented at 502 while the improved stack is represented at 504. The damping constant decreases with decreased temperature and further decreases with the addition of a diffusion barrier due to reduced diffusion of Ta in CoFeB. A MgON diffusion barrier in the improved stack 504 provides optimal diffusion barrier properties, based on various magnetic measurements, while adding minimal series resistance to the stack. The MgON diffusion barrier is fabricated by naturally oxidizing-nitridizing thin layers of Mg films.

FIG. 6 shows the improvement in ratio of critical voltage (V_{c}) for switching to the breakdown voltage of the tunnel barrier layer (V_{bd}) for the improved MTJ stack 602 with an Fe layer having a thickness of 2.5 Å, low temperature anneal, and an MgON diffusion barrier as compared to conventional stacks 604 with no Fe, a high temperature anneal, and no diffusion barrier. A lower V_{c}/V_{bd} is preferred for good yield and reliability of the devices.

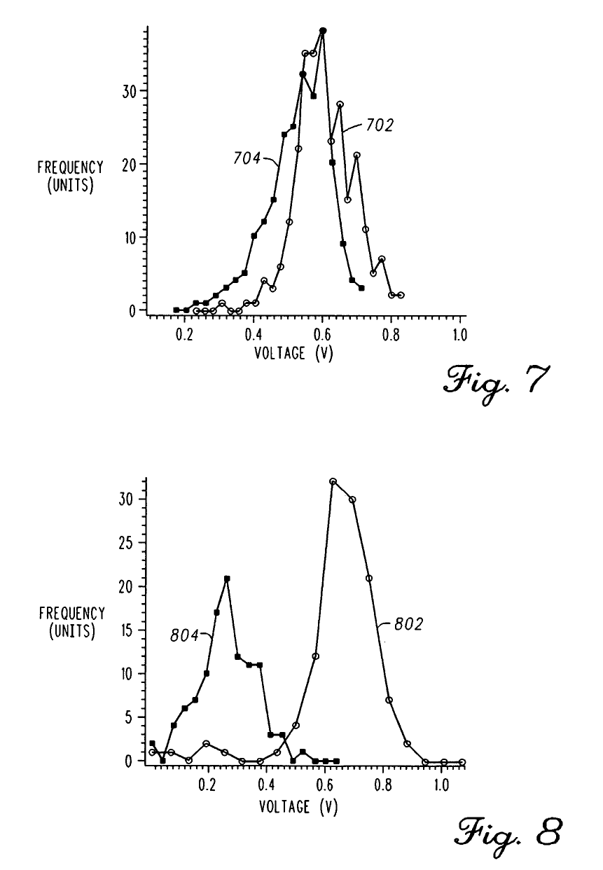

FIGS. 7 and 8 show a comparison of distributions of breakdown (V_{bd}) 702, 802 and critical switching voltage (V_{c}) 704, 804 for devices made with conventional material (FIG. 7) and with improved MTJ stack (FIG. 8). The V_{c} 704 and V_{bd} 702 distributions for conventional material in FIG. 7 clearly overlap, resulting in poor yield and reliability for the memory, since many bits will break down during the write process. The separation of V_{c} 804 and V_{bd} 802 in FIG. 8 for the improved stack is better than in FIG. 7, due to the improved ratio V_{c}/V_{bd}, thus allowing much improved yield and reliability for the memory.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. A magnetic tunnel junction comprising:
a first electrode;
a fixed magnetic element contiguous to the first electrode;
a free magnetic element;
a tunnel barrier disposed between the fixed and free magnetic elements; and
a first layer of iron having a thickness in the range of 0.5 to 5.0 Å disposed adjacent the tunnel barrier.

2. The magnetic tunnel junction of claim 1 wherein the first layer of iron comprises a thickness in the range of 2.5 to 5.0 Å

3. The magnetic tunnel junction of claim 1 wherein the first layer of iron comprises a thickness of about 2.5 Å.

4. The magnetic tunnel junction of claim 1 wherein the first layer of iron comprises a thickness of about 1.0 Å.

5. The magnetic tunnel junction of claim 1 further comprising:
a second electrode; and
a diffusion barrier having a resistance-area product in the range of 4 to 7Ωμ² disposed between the second electrode and the free magnetic element.

6. The magnetic tunnel junction of claim 5 wherein the diffusion barrier comprises MgON.

7. The magnetic tunnel junction of claim 5 wherein the diffusion barrier comprises a thickness between 12.0 Å and 16.0 Å.

8. The magnetic tunnel junction of claim 5 wherein the diffusion barrier is selected from the group consisting of oxides, nitrides, and oxinitrides, wherein the selected oxides, nitrides, and oxinitrides comprise at least one of Al, Mg, Ru, Hf, Zr, Ti, Cu, Nb, Ta, B, or Mo.

9. The magnetic tunnel junction of claim 5 wherein the tunnel barrier comprises MgO.

10. The magnetic tunnel junction of claim 5 wherein the tunnel barrier consists of MgO and the free layer consists of CoFeB, and the fixed magnetic element comprises a pinned layer consisting of CoFe contiguous to the first electrode, a fixed layer consisting of CoFeB contiguous to the tunnel barrier, and a spacer layer consisting of Ru disposed between the fixed layer and the pinned layer.

11. The magnetic tunnel junction of claim 5 wherein the tunnel barrier consists of MgO and the free layer consists of CoFeB, and the fixed magnetic element comprises a pinned layer consisting of CoFe contiguous to the first electrode, a fixed layer consisting of CoFeB contiguous to the tunnel barrier, and a spacer layer consisting of Ru disposed between the fixed layer and the pinned layer, wherein the first layer of iron is disposed between the tunnel barrier and the free layer.

12. The magnetic tunnel junction of claim 5 wherein the tunnel barrier consists of MgO and the free layer consists of CoFeB, and the fixed magnetic element comprises a pinned layer consisting of CoFe contiguous to the first electrode, a fixed layer consisting of CoFeB contiguous to the tunnel barrier, and a spacer layer consisting of Ru disposed between the fixed layer and the pinned layer, wherein the first layer of iron is disposed between the tunnel barrier and the fixed layer.

13. The magnetic tunnel junction of claim 11 further comprising a second layer of iron having a thickness of 0.5 to 5.0 Å being disposed between the tunnel barrier and the fixed layer.

14. A magnetic tunnel junction comprising:
a fixed magnetic element;
a free magnetic element;
a tunnel barrier disposed between the fixed and free magnetic elements;
a layer of iron having a thickness in the range of 0.5 to 5.0 Å disposed contiguous to the tunnel barrier;
an electrode; and
a diffusion barrier having a resistance-area product in the range of 4 to 7Ωμ² disposed between the electrode and the free magnetic element.

15. A method of forming a magnetic tunnel junction, comprising:
forming a fixed magnetic element having a first interface contiguous to a first electrode;
forming a tunnel barrier having a first interface contiguous to a second interface of the fixed magnetic element;
forming a free layer having a first interface contiguous to a second interface of the tunnel barrier;
forming a first layer of iron having a thickness in the range of 1.0 Å to 5.0 Å and disposed adjacent one of the first and second interfaces of the tunnel barrier; and
forming a second electrode over a second interface of the free layer.

16. The method of claim 15 wherein the first layer of iron comprises a thickness in the range of 2.5 to 5.0 Å.

17. The method of claim 15 wherein the first layer of iron comprises a thickness of about 2.5 Å.

18. The method of claim 15 wherein the first layer of iron comprises a thickness of about 1.0 Å.

19. The method of claim 15 further comprising:
forming a diffusion barrier having a resistance-area product in the range of 4 to 7Ωμ² between the free layer and the second electrode.

20. The method of claim 19 wherein the diffusion barrier comprises MgON.

21. The method of claim 19 wherein the diffusion barrier comprises a thickness between 12.0 Å and 16.0 Å.

22. The magnetic tunnel junction of claim 19 wherein the diffusion barrier is selected from the group consisting of the oxides, nitrides, and oxinitrides, wherein the selected oxides, nitrides, and oxinitrides comprise at least one of Al, Mg, Ru, Hf, Zr, Ti, Cu, Nb, Ta, B, or Mo.

23. The method of claim 15 further comprising annealing at a temperature less than 350° C.

24. The method of claim 15 further comprising annealing at a temperature less than 300° C.

25. The method of claim 15 further comprising annealing at a temperature about 265° C.

26. The magnetic tunnel junction of claim 19 wherein the tunnel barrier comprises MgO.

27. The magnetic tunnel junction of claim 15 wherein the tunnel barrier consists of MgO and the free layer consists of CoFeB, and the step of forming the fixed magnetic element comprises forming a pinned layer consisting of CoFe contiguous to the first electrode, forming a fixed layer consisting of CoFeB contiguous to the tunnel barrier, and forming a spacer layer consisting of Ru disposed between the fixed layer and the pinned layer.

28. The magnetic tunnel junction of claim 15 wherein the tunnel barrier consists of MgO and the free layer consists of CoFeB, and the step of forming the fixed magnetic element comprises forming a pinned layer consisting of CoFe contiguous to the first electrode, forming a fixed layer consisting of CoFeB contiguous to the tunnel barrier, and a spacer layer consisting of Ru disposed between the fixed layer and the pinned layer, the first layer of iron disposed between the tunnel barrier and the free layer.

29. The magnetic tunnel junction of claim 15 wherein the tunnel barrier consists of MgO and the free layer consists of CoFeB and the step of forming the fixed magnetic element comprises forming a pinned layer consisting of CoFe contiguous to the first electrode, forming a fixed layer consisting of CoFeB, and forming a spacer layer consisting of Ru disposed between the fixed layer and the pinned layer, the first layer of iron disposed between the tunnel barrier and the fixed layer.

30. The magnetic tunnel junction of claim 28 further comprising forming a second layer of iron having a thickness of 0.5 to 5.0 A between the tunnel barrier and the fixed layer.
